(19) United States
(12) Patent Application Publication
(10) Pub. No.: US 2005/0073249 A1
(43) Pub. Date: Apr. 7, 2005

(54) Organic light-emitting device, manufacturing method thereof, and electronic apparatus thereof

(75) Inventors: Katsuyuki Morii, Suwa-shi (JP); Takeshi Takashima, Fujimi-cho (JP); Hirofumi Hokari, Chino-shi (JP); Rie Makiura, Suwa-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/916,608

(22) Filed: Aug. 12, 2004

(30) Foreign Application Priority Data
Aug. 19, 2003 (JP) 2003-295297

(51) Int. Cl. H05B 33/14; H05B 33/10; B05D 5/06

(52) U.S. Cl. 313/504; 313/503; 313/506; 427/66

(57) ABSTRACT

An organic light-emitting device having a high efficiency in its luminous performance and a long product life, a method of manufacturing an organic light-emitting device, and an electronic apparatus are provided. The organic light-emitting device includes emissive functional layers formed between an anode and a cathode. A hole transport material and a emissive material are mixed in the emissive functional layers, while the hole transport material is provided with a host function, in which the emissive material works as a guest.

### BACKGROUND OF THE INVENTION

1. Field of Invention

The present invention relates to an organic light-emitting device, a manufacturing method thereof, and an electronic apparatus thereof.

2. Description of Related Art

Related art organic light-emitting devices (hereinafter “OLEDs”), including organic substances as a light-emitting display may replace liquid crystal displays. Related art methods to manufacture such OLEDs include a process to form thin films including small-molecular substances by a gas phase method, such as a depositing method, etc., as well as another process to form thin films including polymer substances by a liquid phase method. See Appl. Phys. Lett. 51(12), 21 Sep. 1987, p. 913 and Appl. Phys. Lett. 71(1), 7 Jul. 1997, p. 34.

Further, as for coloring, in case of a small-molecular material, each of different emissive materials is deposited through a mask and formed on a desired pixel. In case of a polymer material, a coloring technology that provides microscopic patterning using an inkjet method is disclosed in Japanese Unexamined Patent Publication No. 10-153967, Japanese Unexamined Patent Publication No. 10-12377 and Japanese Unexamined Patent Publication No. 11-40358.

Furthermore, in a structure of OLEDs, a hole injection and transport layer (hereinafter “a hole transport layer”) are often formed between an anode and an emissive layer in order to enhance the luminous efficiency as well as the durability. See Appl. Phys. Lett. 51(12), 21 Sep. 1987, p. 913. As a method of forming such a hole transport layer, etc., and a buffer layer when using any small-molecular material, Appl. Phys. Lett. 51(12), 21 Sep. 1987, p. 913 discloses a process of forming a phenylamine derivative by depositing. When using any polymer material, a process of forming a conductive polymer material, such as a polythiophene derivative, a polyaniline derivative, etc. into a film by a coating method such as spin-coating is disclosed. See Appl. Phys. Lett. 51(12), 21 Sep. 1987, p. 913.

### SUMMARY OF THE INVENTION

2. The Related Art

OLEDs, described above in relation to the related art technology, are subject to some problems, which are discussed below.

In the case of using a small-molecular material, all of the carrier transfer is carried out among the molecules, and such a small-molecular material is formed to be in an amorphous condition so that the mobility of the carrier has the identical value isotropically. Therefore, to have the highest energy efficiency (to become luminous at a low voltage) it is necessary to provide an interface in parallel with the electrode. Then, a recombination area of the carrier is principally determined by the mobility as far as the carrier injection is sufficient. Consequently, there is a problem in that a plurality of perfect multi layer structures are needed.

In the case of using a polymer material, the mobility in the principal chain direction of the high-molecular weight compound is quite different from that in the inter-molecule direction. Therefore, a parallel arrangement of a layer interface with an electrode does not necessarily result in the highest luminous efficiency.

A structure of OLEDs, in general, includes a hole transport layer, an emissive layer, and an electron transport layer laid in due order. In each layer, a film thickness, a film thickness ratio, and a layer structure are determined by the carrier mobility. For example, in case of a hole transport layer, the thickness of the layer is determined by the hole carrier mobility. However, in case of an emissive layer or an electron transport layer, the thickness of the layer is determined by the electron carrier mobility. In such a manner, the determination on the layer thickness is made so as to transport the holes and electrons to the emissive layer with a good balance.

However, the balance in such a structure is kept by making the layer structure adequate. Then, for example, a problem in the case is that a higher voltage must be set to transport a greater number of holes to have light emission in the emissive layer if the film thickness of the hole transport material is greater. Also, another problem in the case is that uniformity of light emitting positions cannot be obtained.

There has been proposed a related art structure for an OLED including a small-molecular material, in which a hole transport material and a emissive material are mixed, instead of having the layer structure described above. However, just simply mixing a hole transport material and a emissive material results in an imbalance of the mobility of holes and electrons so that a problem arises to deteriorate the luminous efficiency and intensity.

Taking the features described above into consideration, the present invention addresses the problems to simplify the process and enhance the process efficiency. The present invention provides an EL device, with a high efficiency in the luminous performance and a long product life, a manufacturing method thereof, and an electronic apparatus thereof.

An OLED of an exemplary aspect of the present invention includes: an emissive functional layer formed between an anode and a cathode; while a hole transport material and a emissive material are mixed in the emissive functional layer; and the hole transport material is provided with a host function, in which the emissive material works as a guest.

The above description, i.e., “the hole transport material is provided with a host function, in which the emissive material works as a guest.” practically means that an emission spectrum of the hole transport material widely overlaps with an absorption spectrum of the emissive material.

Implementing such a relationship of Host vs. Guest efficiently carries out the energy transfer, and provides enhancement of the luminous efficiency and a long product life.

The “hole transport layer” in the present invention includes a meaning of a “hole injection layer” provided with a hole injection function.

In the OLED of an exemplary aspect of the invention, the hole transport material as well as the emissive material may be polymer materials.

A comparison between a polymer material and a small-molecular material is explained below.

In general, a small-molecular material is formed to be in amorphous condition. Being formed to be in amorphous condition, such a small-molecular material has an isotropic molecular structure. Therefore, in the small-molecular material, the carrier mobility is identical isotropic-wise.

A polymer material is not isotropic and not formed to be in an amorphous condition as a small-molecular material is, so that such a polymer material is provided with a property that the carrier mobility varies due to the chemical structure of the polymer material. Practically, when a comparison is made between the carrier mobility in the principal chain direction of the polymer material and that in the inter-molecule direction, the carrier mobility in the principal chain direction is greater on a two-digit to three-digit scale or more.

Therefore, taking into account the feature of an exemplary aspect of the present invention, i.e., “A hole transport material and a emissive material are mixed in the emissive functional layer”, the small-molecular material is isotropic, and thus mixing the small-molecular material does not cause the carrier mobility to change. By contrast, if the polymer material is mixed, the principal chain of the polymer material gets further elongated among the structure layout in the direction, in which the anode and cathode are facing each other, to bring a greater carrier mobility.

If a polymer material is used for the hole transport material, the hole carrier mobility can be enhanced. Moreover, if a polymer material is used for the emissive material, the electron carrier mobility can be enhanced. Especially, when the polymer material is obtained by polymerizing monomer containing triphenylamine unit, the hole carrier mobility becomes greater and therefore, using such a material is effective.

In the OLED, a molecular weight of the polymer material may be 100,000 or less.

In this event, a polymer material refers to a compound with the chemical structure in which the same unit is placed repeatedly. In a polymer material having its molecular weight of 100,000; the number of the units of the same placed repeatedly is about 1,000 or more.

Therefore, since the molecular weight of the polymer material is 100,000 or less as described above, solubility into a solvent can be enhanced to form a film by a liquid phase process.

Furthermore, in order to enhance the solubility to be higher, it is preferred to use a polymer material within the range of its molecular weight of 5,000, while including 10 to 20 monomer units, up to its molecular weight of 30,000, which almost corresponds to the film thickness of an emissive functional layer.

Still further, in the OLED, an electron transport material may also be mixed in the emissive functional layer.

With such an arrangement; a hole transport material, an electron transport material, and a emissive material are included in the emissive functional layer in a mixed state. Thus, an electron injection layer is placed between the hole transport material and the emissive material described above so that the function of Host vs. Guest relationship between the hole transport material and the emissive material can be promoted.

The “electron transport layer” in the present invention includes a meaning of an “electron injection layer” provided with an electron injection function.

Moreover, a method of manufacturing an OLED of an exemplary aspect of the present invention is to manufacture the OLED that includes emissive functional layer formed between an anode and a cathode, the emissive functional layer being formed by applying a solution, in which a hole transport material and a emissive material are mixed, and the hole transport material being provided with a host function, and the emissive material being handled as a guest.

Implementing such a relationship of Host vs. Guest efficiently carries out the energy transfer, and provides enhancement of the luminous efficiency and a long product life.

In the method of manufacturing an OLED, an electron transport material may also be mixed in the mixed solution.

With such an arrangement, a hole transport material, an electron transport material, and a emissive material are included in the emissive functional layer in a mixed state. Thus, an electron injection layer is placed between the hole transport material and the emissive material described above so that the function of Host vs. Guest relationship between the hole transport material and the emissive material can be promoted.

Also, in the method of manufacturing an OLED, the emissive functional layer may be formed by using a liquid phase process.

The liquid phase process may also be called “a wet process” or “a wet coating process”, in which a substrate and a liquid material get contacted with each other, and more practically the process includes; the inkjet method (droplet discharge method), the spin coating method, the slit coating method, the dip coating method, the spray filming method, the printing method, the droplet discharge method, and so on. After implementing any liquid phase process, heat treatment is generally carried out to dry and heat the liquid material.

The liquid phase process is a suitable method to make a polymer material film. In comparison with a gas phase process, the liquid phase process is able to inexpensively manufacture an OLED without using costly equipment, such as vacuum unit and so on.

In the method of manufacturing an OLED, the liquid phase process may be the droplet discharge method.

The droplet discharge method is a so-called color printing technique known for inkjet printers. In the droplet discharge method, a droplet of a material ink liquefied from each material is discharged onto a transparent substrate out of an inkjet head, and is fixed there. Since the droplet discharge method can discharge each droplet of the material ink precisely into a fine region, it becomes possible to directly fix the material ink into a coloring region as required without photo-lithography. Therefore, being free from any material loss, the droplet discharge method can reduce production costs.

Consequently, using the droplet discharge method makes it possible to form the emissive functional layer inexpensively as well as precisely.

Furthermore, by implementing the droplet discharge method in an exemplary aspect of the present invention as described below, it becomes possible to materialize a unique effect and influence.

If no divide-coating is required to form the emissive functional layer, the spin coating method can be applied or the inkjet method may also be used. However, depending on the method to be used, conditions of the formed film are different.

To describe more in detail; if the emissive functional layer is formed by the spin coating method, a liquid material for the emissive functional layer is applied by centrifugal force in a direction toward a circumferential area of the substrate from the drop position on the substrate. Therefore, the principal chain of the polymer material, which constitutes the emissive functional layer, tends to be formed to be parallel with the substrate.

When being discharged by the droplet discharge method, the liquid material is dispensed from the discharging head in a perpendicular direction onto the substrate. In this situation, drying time is fairly long and can be controlled. Therefore it is possible to form the liquid material into a shape like a yarn ball. As a result, in comparison with that of the spin coating method, the principal chain of the polymer material of the droplet discharge method is not formed to be horizontal to the substrate so that the carrier mobility between the anode and cathode becomes greater and the luminous performance of the OLED can be enhanced.

In the method of manufacturing an OLED, the liquid phase process may use a solvent having solubility of one weight percent or more of the materials (i.e., either combination of the hole transport material and emissive material, or the hole transport material, emissive material, and electron transport material) to constitute the emissive functional layer.

If the solubility is less than one weight percent, the volume of the solvent becomes greater and the solvent drying time after implementing the droplet discharge method becomes longer. Accordingly, this may become a cause of deterioration of productivity, and difficulty in controlling the film thickness. However, the arrangement described above makes each material to form the emissive functional layer appropriately dissolved in the solvent, and it brings an appropriate liquid material to form the emissive functional layer by using a liquid phase process described above, especially by using the droplet discharge method.

The solubility ratio of the hole transport material, emissive material, and electron transport material in such a solvent is the same as the composition ratio (mixing ratio) of the materials to constitute the emissive functional layer.

Also, it is possible to use a solvent prepared by mixing various kinds of solvents.

In the method of manufacturing an OLED, it is preferred that at least one of the anode and the cathode may be formed by using the liquid phase process.

In the related art, a gas phase process was used in general for a forming process of an anode and a cathode. However, if the anode and cathode are formed by a liquid phase process, it becomes possible to form all of the anode, the emissive functional layer, and the cathode by a liquid phase process.

Therefore, any costly equipment, such as a vacuum unit and so on is not required and the production process, can be simplified so that an OLED can be manufactured inexpensively.

Also, it is possible in the present invention to use a gas phase process, such as the vacuum deposition method to form an anode and a cathode.

Moreover, an electronic apparatus of an exemplary aspect of the present invention includes an OLED described above. Therefore it is possible to provide an electronic apparatus that has a long product life and can carry out bright displaying.

### BRIEF DESCRIPTION OF THE DRAWINGS

FIG. 1 is a schematic to show an OLED to be manufactured through a method of an exemplary embodiment of the present invention;

FIG. 2 is a schematic for explaining a process of manufacturing the OLED shown in FIG. 1;

FIG. 3 is a schematic for explaining a process of manufacturing the OLED shown in FIG. 1;

FIG. 4 is a schematic for explaining a process of manufacturing the OLED shown in FIG. 1;

FIG. 5 is a schematic for explaining a process of manufacturing the OLED shown in FIG. 1;

FIG. 6 is a schematic for explaining a process of manufacturing the OLED shown in FIG. 1;

FIG. 7 is a schematic for explaining a process of manufacturing the OLED shown in FIG. 1;

FIG. 8 is a schematic for explaining a process of manufacturing the OLED shown in FIG. 1;

FIG. 9 is a graph for explaining a function of Host vs. Guest relationship;

FIG. 10 is a schematic for comparing the inkjet method with the spin coating method;

FIG. 11 is a graph for explaining a luminous performance of an OLED of the present invention;

FIG. 12 is a graph for explaining a case in which an electron transport material is added into an emissive functional layer; and

FIG. 13(a)-13(c) are schematics to show electronic devices equipped with an OLED of the present invention.

### DETAILED DESCRIPTION OF EXEMPLARY EMBODIMENTS

The following sections describe an exemplary embodiment of the present invention.

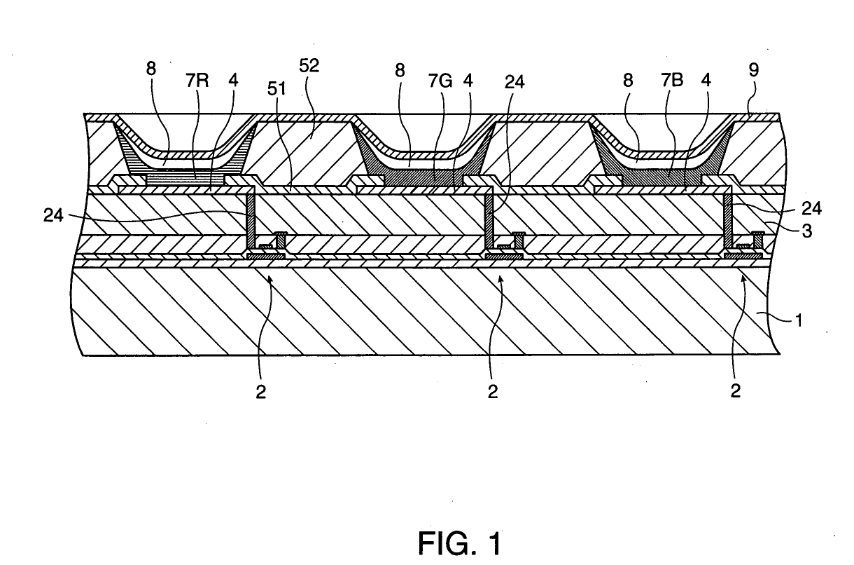

A method of manufacturing an OLED, which corresponds to an exemplary embodiment of the present invention, is described by referring to FIG. 1 to FIG. 10. In each drawing, a magnifying scale for each layer and each material component is different part by part to show each layer and each material component in recognizable size on the drawing.

The OLED to be manufactured here is a color OLED. As shown in FIG. 1; while a first organic EL element being equipped with a red emissive layer 7R, a second organic EL element being equipped with a green emissive layer 7G, and a third organic EL element being equipped with a blue emissive layer 7B; each organic EL element works as a pixel and eventually multiple pixels are placed on a substrate to have each pixel at a required position.

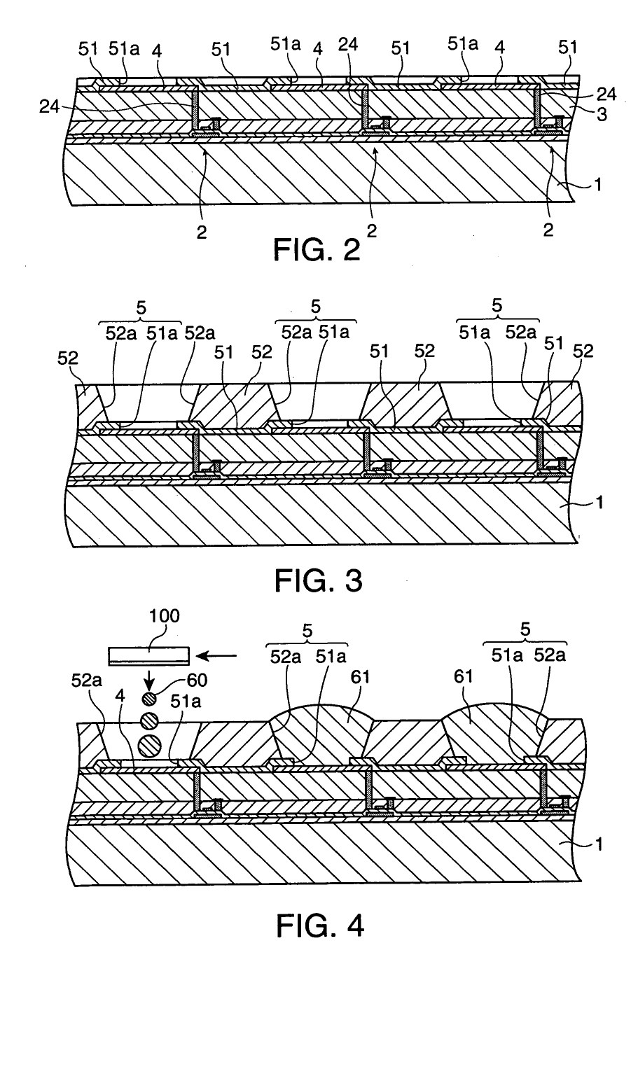

As shown in FIG. 2; on a glass substrate 1, a thin-film transistor 2 for each pixel is formed at first, and then an insulation layer 3 is placed. Next, a wiring 24 is formed to connect the thin-film transistor 2 for each pixel and an anode 4 (pixel electrode) in the insulation layer 3. Then, the anode 4 including an ITO (In₂O₃—SnO₂) corresponding to each pixel position is formed by ordinarily implementing an ITO thin-film forming process, a photolithography process, and an etching process. As a result, the anode 4 including an ITO is formed at each pixel position on the glass substrate 1 after forming the wiring 24.

Next, a first partition wall 51, which is equipped with an opening 51a corresponding to each light emitting region and made of silicone oxide, is formed on the glass substrate 1 by ordinarily implementing a silicone oxide thin-film forming process, a photolithography process, and an etching process. FIG. 2 shows the condition of the above treatment. The first partition wall 51 is formed so as to make a circumferential edge part of the opening 51a overlap an outer edge part of the anode 4.

Next, as shown in FIG. 3, a second partition wall 52, which is equipped with an opening 52a corresponding to each light emitting region, is formed onto the first partition wall 51. The second partition wall 52 is made of polyamide resin, and is formed by implementing a coating process with a solution containing polyamide resin, a drying process for the coated film, a photolithography process, and an etching process.

The opening 52a of the second partition wall 52 has a tapered shape in its section perpendicular to the substrate. Specifically, the opening is narrow at the side near the glass substrate 1 and it becomes wider toward the direction away from the glass substrate 1. The area of the opening 52a of the second partition wall 52, at the position closest to the glass substrate 1, is still greater than the opening 51a of the first partition wall 51. Thus, the partition wall having an opening 5 provided with a two-step structure is materialized.

The light emitting region of each pixel is precisely controlled by the opening 51a of the first partition wall 51. Then, the second partition wall 52 has its specified thickness to secure the depth of the opening 5, and it is provided with a tapered section that enables a dropped solution to easily enter the opening 5 even if the dropped solution is placed onto the top surface of the second partition wall 52.

Next, as shown in FIG. 4, a solution 60 containing a material to form an emissive functional layer is dropped toward each of the anode 4 from a position above each of the opening 5 by the inkjet method (droplet discharge method). A reference numeral 100 in FIG. 4 corresponds to an inkjet head. Thus, a droplet 61 of the solution is formed onto each of the pixel electrode 4 (anode 4).

On this occasion, the material to form an emissive functional layer refers to material in which a hole transport material and a emissive material are mixed appropriately. In this exemplary embodiment, the most important feature is that the hole transport material is provided with a host function, in which the emissive material works as a guest. Another feature is, that the hole transport material and the emissive material are prepared by using a polymer material. Then, it is preferable that a molecular weight of the polymer material may be 100,000 or less, and a total length of a molecule of the polymer material may be equal to a film thickness of the emissive functional layer.

A polymer material, having triphenylamine as a skeleton of its chemical structure is used as the hole transport material. In this exemplary embodiment; ADS254BE made by American Dye Source Inc. and shown below as Chemical compound 1, is used. Any of the materials indicated below as Chemical compounds 2 through 6 can be used as the emissive material; i.e., a polyolefin-basepolyofluorene-base polymer derivative, a (poly-) p-phenylenevinylene derivative, a polyphenylene derivative, a poly(9-vinylcarbazole), a polythiophene derivative, a perylene-base dye, a coumarin-base dye, a rhodamine-base dye, or any of the above polymer materials in which an organic EL material is doped. The material to be doped may include; rubrene, perylene, 9,10-diphenylanthracene, tetraphenyl butadiene, Nile red, coumarin 6, quinacridone, and so on.

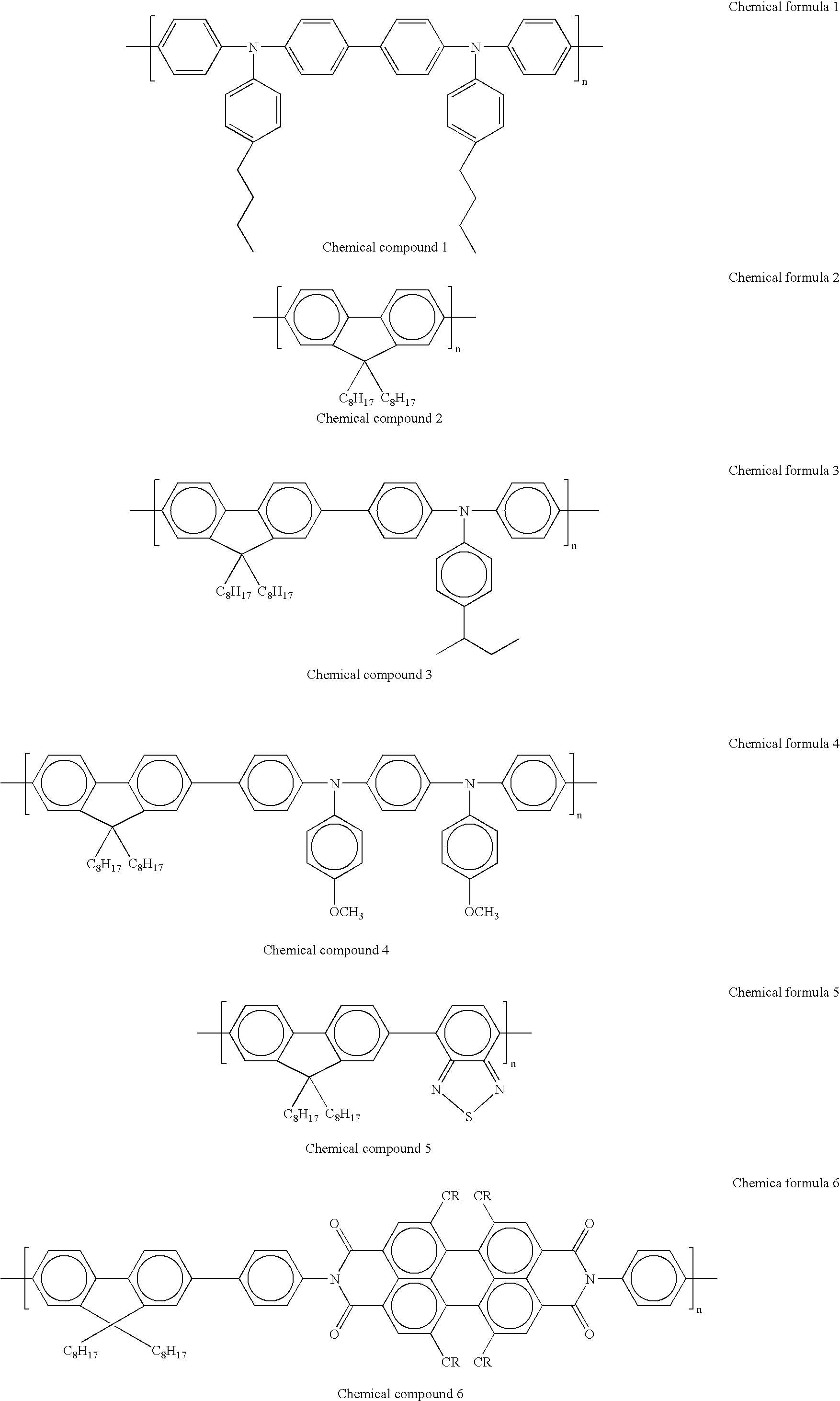

Also, it is possible to use, for example MEH-PPV poly[2-methoxy-5-(2-ethyl hexyloxy)-p-phenylenevinylene] as a red emissive material, for example poly(9,9-dioethylfluorene) as a blue emissive material, and for example PPV poly(p-phenylenevinylene) as a green emissive material.

Moreover, a molecular weight of a polymer material to constitute such a hole transport material and a emissive material may be 100,000 or less; especially, more than 5,000 and less than 30,000.

A mixing ratio of the hole transport material and the emissive material is 1:2 in weight percent to make a material for an emissive functional layer. Xylene is used as a solvent to dissolve the material for an emissive functional layer. Also, it is possible to use another solvent besides xylene, for example, such as cyclohexylbenzene, dihydrobenzofuran, trimethylbenzene, tetramethylbenzene. On this occasion, the solubility of each material (emissive material, and hole transport material) in the solvent may be one weight percent or more.

Then, the function of Host vs. Guest relationship between the hole transport material and the emissive material is described below by referring to FIG. 9.

In FIG. 9, the solid line curve indicated with the note “HTL” and the broken line curve indicated with the note “EML” show an emission spectrum of the hole transport material and an absorption spectrum of the emissive material, respectively.

As FIG. 9 shows, a feature of an exemplary aspect of the present invention; i.e., “the hole transport material is provided with a host function, in which the emissive material works as a guest.” practically means that the emission spectrum “HTL” of the hole transport material widely overlaps with the absorption spectrum “EML” of the emissive material.

Then, the condition of the polymer material in two cases; i.e., when the material for the emissive layer is applied by using the inkjet method or when the material for the emissive functional layer is applied by using the spin coating method, is described below in comparison by referring to FIG. 10.

As FIG. 10 shows, if the material for the emissive functional layer is formed by the spin coating method, the material for the emissive functional layer is applied by centrifugal force in the direction toward a circumferential area of the substrate from the drop position on the substrate. Therefore, the principal chain of the polymer material, which constitutes the emissive functional layer, tends to be formed to be parallel with the substrate.

When being discharged by the inkjet method, the material for the emissive functional layer is dispensed from a discharging head in the perpendicular direction onto the substrate. In the situation, drying time is fairly long and can be controlled. Therefore it is possible to form the material into a shape like a yarn ball. As a result, in comparison with that of the spin coating method, the principal chain of the polymer material in the droplet discharge method is not formed to be parallel with the substrate so that the carrier mobility between the anode and cathode becomes greater and the luminous performance of the OLED can be enhanced.

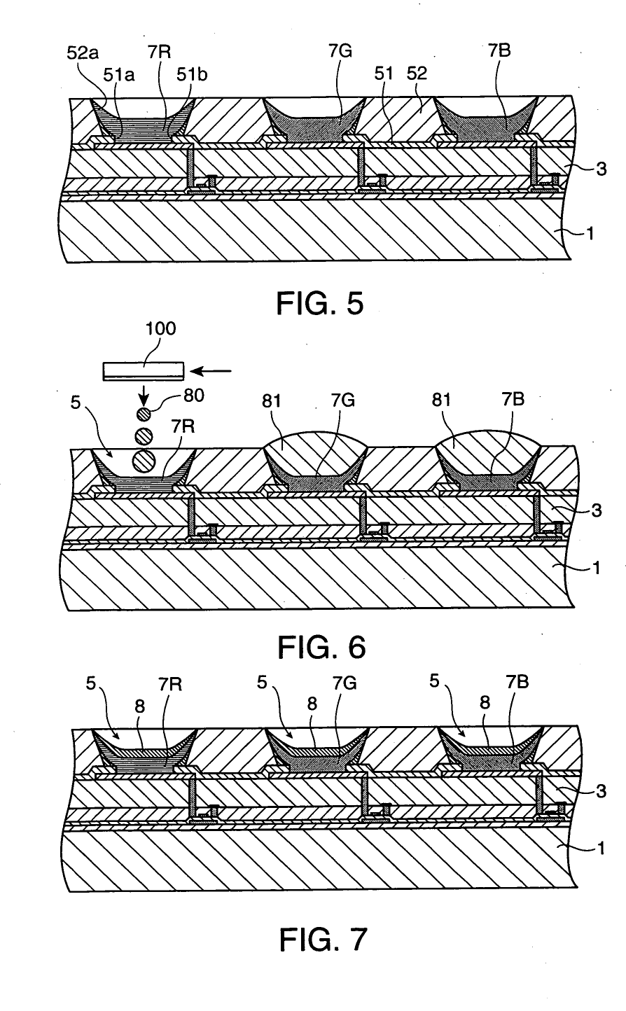

Returning to FIG. 5, the next section below continues to describe a method of manufacturing an OLED.

At this stage, a drying process is put into practice to vaporize the solvent out of the droplet 61. Thus, a corresponding luminous function layer 7R, 7G or 7B for each color is formed on each pixel electrode 4, as FIG. 5 shows.

Next, as shown in FIG. 6, a dispersion liquid 80 containing an ultra-fine particle (average particle size: larger than 1 nm and smaller than 100 μm) of ytterbium (Yb) is dropped toward each luminous function layer 7R, 7G or 7B for each color from a position above each of the openings 5 by the inkjet method. The reference numeral 100 in FIG. 6 corresponds to an inkjet head. Thus, a droplet 81 of the dispersion liquid is formed onto each of the luminous function layers 7R, 7G, and 7B.

The ultra-fine particle of ytterbium (Yb) can be obtained through the following procedures (solvent trap method) by using the gas evaporation method. That is to say; ytterbium is vaporized under the pressure condition of 0.5 torr of helium, and then tridecane vapor gets contacted with the ultra-fine particle of ytterbium still in intermediate condition and those material components are cooled down. As a result; a dispersion liquid, in which an ultra-fine particle of ytterbium is dispersed in tridecane, is obtained. This dispersion liquid can be used as the dispersion liquid 80.

Next, a drying process is put into practice to vaporize the solvent out of the droplet 81. Such a drying process can be implemented by maintaining the object in an inert gas environment at temperature 150 degrees Celsius. As a result, a cathode layer (first cathode) 8 made of ytterbium is formed onto each of the emissive functional layers 7R, 7G, and 7B, as FIG. 7 shows.

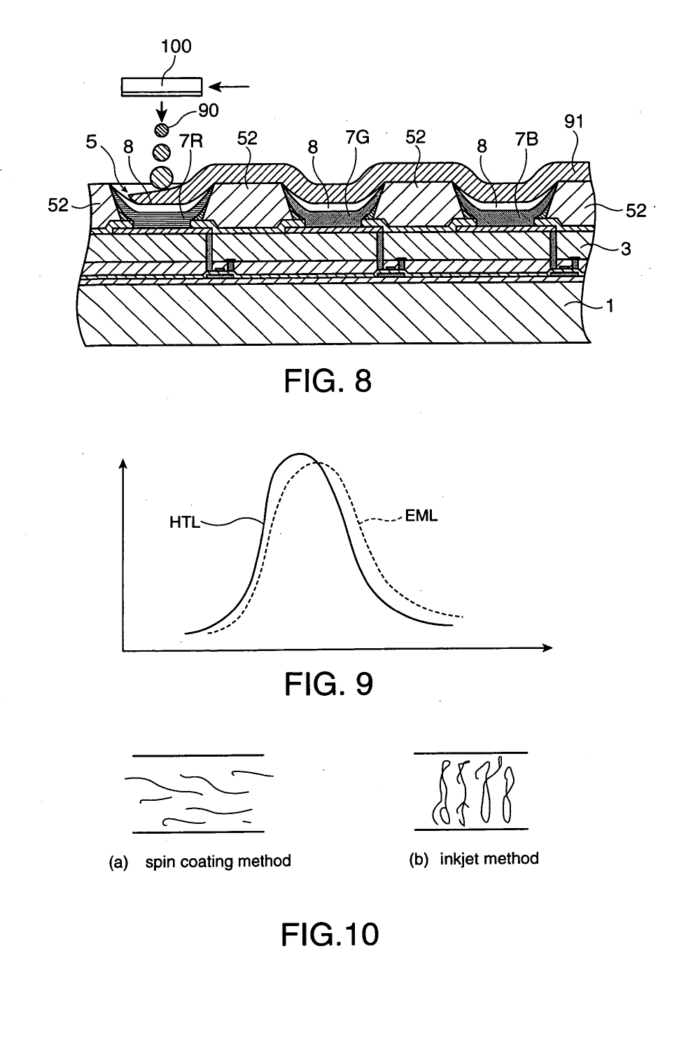

Next, as shown in FIG. 8, a dispersion liquid 90 containing a conductive fine particle is dropped onto the entire top surface of the substrate 1 under the condition shown in FIG. 7 by the inkjet method. As the dispersion liquid 90, a dispersion liquid containing a fine particle made of gold or silver can be used. “PERFECT GOLD” made by Vacuum Metallurgical Co., Ltd. or a dispersion liquid of ultra-fine silver particle, which can be obtained by adding sodium citrate solution into silver nitrate solution, can be used. The reference numeral 100 in FIG. 8 corresponds to an inkjet head. Thus, a liquid layer 91 of the dispersion liquid is formed on the first cathode layer 8 in each opening 5 as well as on the second partition wall 52.

Next, a drying process is put into practice to vaporize the solvent out of the liquid layer 91. Thus, as shown in FIG. 1, a second cathode 9 is formed all over the substrate 1 (i.e., over the first cathode 8 in the opening 5 that corresponds to a pixel region, as well as the second partition wall 52).

Then, an epoxy-resin-base adhesive is applied with a specified thickness all over the top surface of the substrate 1 and an outer surface of the second partition wall 52, positioned on the periphery of the substrate. Subsequently, while having a glass plate placed on the surfaces, the adhesive gets hardened. The entire top surface of the second cathode 9 is covered with the epoxy-resin-base adhesive. Thus, by sealing with the sealant and the glass plate, an organic light-emitting display panel, which constitutes an OLED, is now completed.

An OLED can be obtained by placing the organic light-emitting display panel onto a main body equipped with a driver circuit and so on.

Next, the luminous performance of the OLED described above is explained by referring to FIG. 11.

In FIG. 11, the horizontal axis and the vertical axis each correspond to the driving voltage (V) and the luminous efficiency, respectively. In the figure, the curve indicated with the symbol “A” shows the luminous performance of the OLED formed by mixing the hole transport material and the emissive material described above (this OLED structure is hereinafter called “Mix structure A”), while the curve indicated with the symbol “B” shows the luminous performance of the OLED formed with a multi-layer structure of the hole transport material and the emissive material in the same manner as a related art method (this OLED structure is hereinafter called “Multi-layer structure B”).

As FIG. 11 shows, it is concluded that the threshold voltage of Mix structure A is lower in comparison with that of Multi-layer structure B (Refer to the section “X” in the figure). Moreover, it is also concluded that the maximum luminous efficiency of the Mix structure A is higher than that of the Multi-layer structure B (Refer to the section “Y” in the figure). Furthermore, as a result, the graphed area with a higher voltage shows that the Mix structure A has a less decline in the luminous efficiency, and suggests a wide spread of the luminous region.

As described above, in this exemplary embodiment; the hole transport material is provided with a host function, in which the emissive material works as a guest. Therefore, the emission spectrum of the hole transport material widely overlaps with the absorption spectrum of the emissive material so that a relationship of Host vs. Guest is implemented to efficiently carry out the energy transfer, and to provide enhancement of the luminous efficiency and a long product life.

Furthermore, in an emissive functional layer 7, there are mixed a hole transport material and a emissive material. Therefore, a principal chain of a polymer material is elongated and placed in a direction, in which an anode and a cathode face each other, so that a high carrier mobility can be obtained.

When a polymer material is used for the hole transport material, the hole carrier mobility can be enhanced. Also, when a polymer material is used for the emissive material, the electron carrier mobility can be enhanced.

Since the molecular weight of the polymer material is 100,000 or less, solubility into a solvent can be enhanced to form a film by the inkjet method. Furthermore, if any polymer material within the range of its molecular weight of 5,000 up to 30,000 is used, the solubility can be enhanced more adequately to become higher.

Further, since the inkjet method is used to form the emissive functional layer 7, it becomes possible to directly fix a material ink into a coloring region as required without photo-lithography. Therefore, being free from any material loss, the inkjet method can reduce production costs. Consequently, using such a droplet discharge method makes it possible to form the emissive functional layer 7 inexpensively as well as precisely.

Moreover, in the inkjet method, drying time for the material for the emissive functional layer is fairly long and can be controlled so that it is possible to form the liquid material into a shape like a yarn ball. As a result, in comparison with that of the spin coating method, the principal chain of the polymer material in the inkjet method is not formed to be parallel with the substrate so that the carrier mobility between the anode 4 and the cathode 8 becomes greater and the luminous performance of the OLED can be enhanced.

Furthermore, since solubility of each material to constitute the emissive functional layer 7 is one weight percent or more, the material to constitute the emissive functional layer 7 is appropriately dissolved in the solvent to bring an appropriate liquid material to form the emissive functional layer 7 by using the inkjet method.

Moreover, since the cathode 8 to form by using the inkjet method, it becomes possible to form all of the emissive functional layer 7 and the cathode 8 by a liquid phase process.

Therefore, any costly equipment, such as a vacuum unit etc., is not required and the production process can be simplified so that an inexpensive OLED can be manufactured.

In the exemplary embodiment described above, the material for the emissive functional layer has a composition structure in which the hole transport material and the emissive material are mixed. However, an electron transport material may also be added into the material for the emissive functional layer.

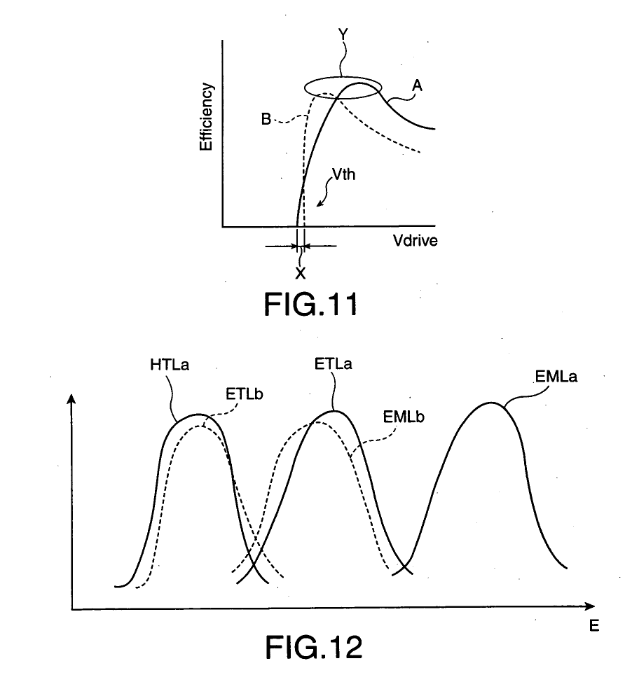

Then, the function of Host vs. Guest relationship in an emissive functional layer formed by mixing a hole transport material, a emissive material, and an electron transport material is described below by referring to FIG. 12.

In FIG. 12 the solid line curve indicated as “HTLa” shows an emission spectrum of the hole transport material, the solid line curve indicated as “ETLa” shows an emission spectrum of the electron transport material, the broken line curve indicated as “ETLb” shows an absorption spectrum of the electron transport material, the solid line curve indicated as “EMLa” shows an emission spectrum of the emissive material, and the broken line curve indicated as “EMLb” shows an absorption spectrum of the emissive material.

As FIG. 12 shows, the emission spectrum “HTLa” of the hole transport material widely overlaps with the absorption spectrum “ETLb” of the electron transport material. The emission spectrum “ETLa” of the electron transport material widely overlaps with the absorption spectrum “EMLb” of the emissive material. Thus, an electron injection layer is placed between the hole transport material and the emissive material so that the function of Host vs. Guest relationship between the hole transport material and the emissive material can be promoted.

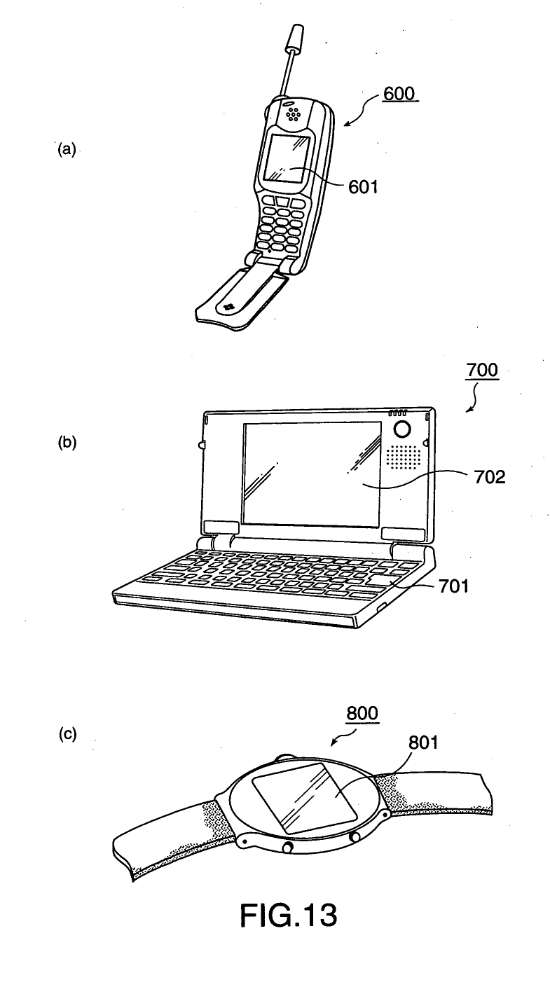

An OLED of an exemplary aspect of the present invention can be applied, for example, to various electronic apparatus shown in FIG. 13.

FIG. 13(a) is a schematic of a cellular phone as an example. In FIG. 13(a), a reference numeral 600 indicates a main body of the cellular phone, while a reference numeral 601 corresponds to a display section using the OLED.

FIG. 13(b) is a schematic of a portable data processing unit, such as a word processor, a personal computer, and so on, as an example. In FIG. 13(b), a reference numeral 700 indicates a data processing unit, a reference numeral 701 corresponds to a data input section, such as a keyboard, a reference numeral 703 represents a main body of the data processing unit, and a reference numeral 702 indicates a display section using the OLED.

FIG. 13(c) is a schematic of a wristwatch-type electronic device, as an example. In FIG. 13(c), a reference numeral 800 indicates a main body of the wristwatch, and a reference numeral 801 corresponds to a display section using the OLED.

Each of the electronic apparatus shown in FIG. 13(a) through FIG. 13(c) is equipped with an OLED, to be manufactured through the manufacturing method of the exemplary embodiment described above, as a display section. These apparatus are provided with the features of the manufacturing method for the OLED of the exemplary embodiment described above. Therefore, the manufacturing method for these electronic apparatus becomes easier.

In the exemplary embodiment described above, the cathode layer to be made of ytterbium is formed by using a dispersion liquid containing an ultra-fine particle of ytterbium through a liquid phase process. A method of an exemplary embodiment of the present invention is not confined to using a dispersion liquid of an ultra-fine particle of a rare-earth element. For example, the method of an exemplary aspect of the present invention also includes those methods in which, after dropping a liquid containing a complex of a rare-earth element by the inkjet method and so on, a treatment to remove a ligand of the complex is carried out.

In the exemplary embodiment described above, the OLED is explained. However, the exemplary embodiment can also be adopted to any OLED other than those display units, such as a light source etc. Regarding materials etc., to constitute other structure element other than the cathode of the OLED, any suitable material may be applied.

1. An organic light-emitting device, comprising:
an anode;
a cathode;
an emissive functional layer formed between the anode and the cathode,
a hole transport material and a emissive material mixed in the emissive functional layer and the hole transport material being provided with a host function, in which the emissive material works as a guest.

2. The organic light-emitting device according to claim 1, the hole transport material being a polymer material.

3. The organic light-emitting device according to claim 2, the polymer material being obtained by polymerizing monomer containing triphenylamine unit.

4. The organic light-emitting device according to claim 1, the emissive material being a polymer material.

5. The organic light-emitting device according to claim 2, a molecular weight of the polymer material being 100,000 or less.

6. The organic light-emitting device according to claim 2, a molecular weight of the polymer material being within a range from 5,000 to 30,000.

7. The organic light-emitting device according to claim 1, an electron transport material being also mixed in the emissive functional layer.

8. A method of manufacturing an organic light-emitting device that includes an emissive functional layer formed between an anode and a cathode, the method comprising,
forming the emissive functional layer by applying a solution in which a hole transport material and a emissive material are mixed, the hole transport material being provided with a host function, in which the emissive material is handled as a guest.

9. The method of manufacturing an organic light-emitting device according to claim 8, including mixing an electron transport material in the mixed solution.

10. The method of manufacturing an organic light-emitting device according to claim 8, including forming the emissive functional layer by using a liquid phase process.

11. The method of manufacturing an organic light-emitting device according to claim 10, the liquid phase process being a droplet discharge method.

12. The method of manufacturing an organic light-emitting device according to claim 8 further comprising: using a solvent, having solubility of one weight percent or more of the dissolved hole transport material and the dissolved emissive material.

13. The method of manufacturing an organic light-emitting device according to claim 9, further comprising:
a solvent having solubility of one weight percent or more of the dissolved hole transport material, the dissolved emissive material, and the dissolved electron transport material.

14. The method of manufacturing an organic light-emitting device according to claim 8, including forming one of the anode and cathode by using a liquid phase process.

15. The method of manufacturing an organic light-emitting device according to claim 8, including forming both the anode and cathode by using a liquid phase process.

16. An electronic apparatus, comprising:
an organic light-emitting device according to claim 1.
